(19) United States
(12) Patent Application Publication
(10) Pub. No.: US 2014/0014402 A1
(43) Pub. Date: Jan. 16, 2014

(54) EPOXY RESIN COMPOSITION FOR BUILD-UP INSULATING FILM, INSULATING FILM FORMED THEREFROM, AND MULTILAYER PRINTED CIRCUIT BOARD HAVING THE SAME

(71) Applicant: SAMSUNG ELECTRO-MECHANICS CO., LTD., Suwon (KR)

(72) Inventors: Jae Choon Cho, Suwon (KR); Jong Yoon Jang, Suwon (KR); Chung Hee Lee, Suwon (KR); Hee Sun Chun, Suown (KR); Sung Hyun Kim, Suwon (KR); Choon Keun Lee, Suwon (KR)

(21) Appl. No.: 13/939,743

(22) Filed: Jul. 11, 2013

(30) Foreign Application Priority Data
Jul. 12, 2012 (KR) 10-2012-0076253

(51) Int. Cl. H01B 3/40; H05K 1/03

(52) U.S. Cl. CPC H01B 3/40; H05K 1/0373
USPC 174/258; 523/400; 523/466; 523/457; 523/458

(57) ABSTRACT

This invention relates to an epoxy resin composition, an insulating film formed therefrom, and a printed circuit board, and more particularly to an epoxy resin composition including an epoxy resin, an acid anhydride curing agent, etc., which exhibits improved dielectric properties by decreasing permittivity, dielectric tangent, etc. in a build-up type multilayer printed circuit board, and to an insulating film manufactured using the epoxy resin composition, and to a multilayer printed circuit board in which inner circuits formed of copper (Cu) are insulated by virtue of the insulating film to thus form multiple layers.

### CROSS-REFERENCE TO RELATED APPLICATION

This application claims the benefit of Korean Patent Application No. 10-2012-0076253, filed Jul. 12, 2012, entitled “Epoxy resin composition for build-up insulating film, insulating film made therefrom, and multilayer printed circuit boards having the same,” which is hereby incorporated by reference in its entirety into this application.

### BACKGROUND OF THE INVENTION

1. Technical Field

The present invention relates to an epoxy resin composition for a build-up insulating film, an insulating film formed therefrom, and a multilayer printed circuit board having the same.

2. Description of the Related Art

With the technical advancement of electronic devices and the increased demand for complicated functions thereof, electronic devices are being manufactured so as to have high performance, and thus designs able to achieve high density, high functionality, miniaturization, slimness, and low weight and also able to be used at high frequencies are required. Also, in printed circuit boards (PCBs), wiring should become fine and very dense as build-up layers in a double structure form are provided. Hence, insulating layers have to have high performance and high density, and standards required for electrical, mechanical, and thermal properties are becoming increasingly stringent.

The development of integrated circuits (ICs) enables miniaturization and high integration, making it possible to achieve multifunctionality and high performance. Thus, by virtue of mounting of such ICs, interposers, packages, PCBs, etc., which are used to accomplish electrical connections with other devices, have to be highly integrated.

As conventional multilayer boards are configured such that inner circuits are provided and all parts are mounted on the board, there is an increasing demand for developing embedded boards in which a plurality of parts or some parts are embedded in the multilayer board to thereby further increase the degree of integration and to achieve miniaturization and high performance. Boards or packages, in which 3D mounting/embedding of parts may increase the mounting density to reduce the size and to improve electrical performance at high frequencies, are referred to as embedded PCBs. The embedded PCBs are multilayer boards in which semiconductors and passive parts are embedded to exhibit high density, high functionality, and high frequency properties.

As the size and weight of set devices are decreased, the related large-scale integration (LSI) is being miniaturized, and the miniaturization of LSI is possible due to fineness of ICs, etc., but power consumption and mounting of chip parts may become problematic, and thus embedded PCBs using application to passive parts and direct processing of passive elements (L,C,R) in the inner layers thereof are required. As such, a low-loss insulating material functions as a support material for maintaining rigidity of packages while acting as an insulating material between wires of the embedded PCBs or between functional devices.

Meanwhile, in the case of LSI, an operating frequency increases to process a large amount of information in a short period of time. Furthermore, a higher wiring density is required in packages, and transfer loss is increased and the delay time of the signal is lengthened due to the use of fine wires. Thereby, noise between wires may further increase, and thus parasitic capacitance should be lowered by decreasing the permittivity of the insulating material used. In order to reduce dielectric loss, the dielectric loss of the material should also be lowered. The low-loss insulating material may be utilized to embed functional devices such as radio frequency (RF) filters, signal matching capacitors, etc. Therefore, the development of such a low-loss insulating material is essential to actually use organic system modules.

With the goal of solving the problems, Patent Document 1 discloses a resin composition which comprises a cyanate ester resin and a naphthalene ether type epoxy resin, and is thus improved in dielectric properties. Also, Patent Document 2 discloses a resin composition which comprises a liquid crystal polyester and an epoxy group-containing ethylene copolymer, and is thus improved in dielectric properties. However, there is a recent need for an insulating material having improved dielectric properties such as lower permittivity and dielectric tangent.
Patent Document 1: Korean Unexamined Patent Publication No. 2011-0068877
Patent Document 2: Korean Unexamined Patent Publication No. 2006-0131916

### SUMMARY OF THE INVENTION

Culminating in the present invention, intensive and thorough research with the aim of solving the problems occurring in the related art resulted in the finding that, when an epoxy resin composition is cured by using an acid anhydride curing agent having a value of molar polarizability/molar volume of 0.6 or less as a curing agent contained in the epoxy resin composition, dielectric loss may be lowered, thus reducing the dielectric loss of the insulating material.

Accordingly, a first aspect of the present invention is to provide an epoxy resin composition for a build-up insulating film, which has low permittivity and dielectric tangent.

A second aspect of the present invention is to provide an insulating film which is manufactured from the epoxy resin composition, thus enabling the formation of a fine circuit pattern.

A third aspect of the present invention is to provide a multilayer printed circuit board having the insulating film.

In order to accomplish the above first aspect of the present invention, an epoxy resin composition is provided, which comprises an epoxy resin (A), an acid anhydride curing agent (B) having a value of molar polarizability/molar volume of 0.6 or less and having a fluorine group or a methyl group in a molecule thereof with a symmetric molecular structure, an inorganic filler (C), and a curing accelerator (D).

The epoxy resin composition of the present invention may comprise 100 parts by weight of the epoxy resin, 80˜120 parts by weight of the acid anhydride curing agent, 60˜160 parts by weight of the inorganic filler, and 0.1˜1.5 parts by weight of the curing accelerator.

In the epoxy resin composition of the present invention, the acid anhydride curing agent having the value of molar polarizability/molar volume of 0.6 or less and having the fluorine group or the methyl group in the molecule thereof with the symmetric molecular structure may be at least one selected from the group consisting of 2,2′-bis-(3,4-dicarboxyphenyl)hexafluoropropane dianhydride, 1,2,3,4-cyclopentane tetracarboxylic acid dianhydride, 1,2,3,4-cyclobutane tetracarboxylic acid dianhydride, and 1,2,4,5-cyclohexane tetracarboxylic acid dianhydride.

In the epoxy resin composition of the present invention, the inorganic filler (C) may be at least one selected from the group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

In the epoxy resin composition of the present invention, the curing accelerator (D) may be at least one selected from the group consisting of 2-methylimidazole, 2-undecylimidazole, 2-heptanedecylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-cyanoethyl-2-undecyl-imidazolium trimellitate, 1-cyanoethyl-2-phenyl-imidazolium trimellitate, 2,4-diamino-6-(2′-methylimidazol-(1′))-ethyl-s-triazine, 2,4-diamino-6-(2′-ethyl-4-methylimidazol-(1′))-ethyl-s-triazine, 2,4-diamino-6-(2′-undecyl imidazol-(1′))-ethyl-s-triazine, 2-phenyl-4,5-dihydroxy-methylimidazole, 2-phenyl-4-methyl-5-hydroxymethylimidazole, 2-phenyl-4-benzyl-5-hydroxymethylimidazole, 4,4′-methylenebis-(2-ethyl-5-methylimidazole), 2-aminoethyl-2-methylimidazole, 1-cyanoethyl-2-phenyl-4,5-di(cyanoethoxymethyl)imidazole, 1-dodecyl-2-methyl-3-benzylimidazolium chloride, and imidazole-containing polyamide.

The epoxy resin composition of the present invention may further comprise at least one of a cyanate ester resin and a bismaleimide resin.

The epoxy resin composition of the present invention may further comprise at least one thermoplastic resin selected from the group consisting of a phenoxy resin, a polyimide resin, a polyamideimide (PAI) resin, a polyetherimide (PEI) resin, a polysulfone (PS) resin, a polyethersulfone (PES) resin, a polyphenylene ether (PPE) resin, a polycarbonate (PC) resin, a polyetheretherketone (PEEK) resin, and a polyester resin.

In order to accomplish the above second aspect of the present invention, an insulating film is provided, which is manufactured using the epoxy resin composition as above.

In order to accomplish the above second aspect of the present invention, a multilayer printed circuit board is provided, which comprises the insulating film as above.

### BRIEF DESCRIPTION OF THE DRAWING

FIG. 1 is a cross-sectional view illustrating a typical printed circuit board to which a build-up insulating film manufactured from an epoxy resin composition according to the present invention may be applied.

### DESCRIPTION OF SPECIFIC EMBODIMENTS

Before the present invention is described in more detail, it must be noted that the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention. Further, the embodiments of the present invention are merely illustrative, and are not to be construed to limit the scope of the present invention, and thus there may be a variety of equivalents and modifications able to substitute for them at the point of time of the present application.

In the following description, it is to be noted that embodiments of the present invention are described in detail so that the present invention may be easily performed by those skilled in the art, and also that, when known techniques related to the present invention may make the gist of the present invention unclear, a detailed description thereof will be omitted.

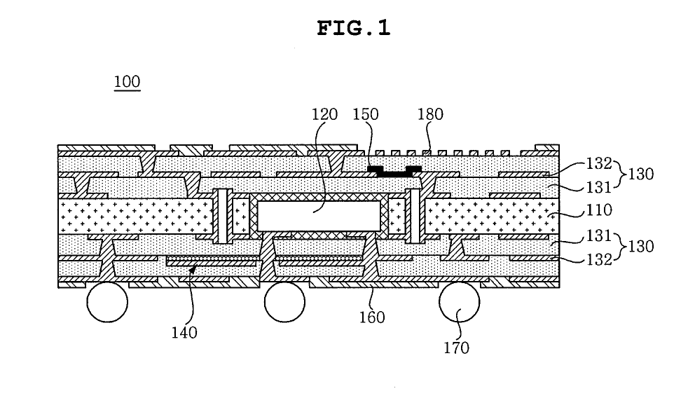

FIG. 1 is a cross-sectional view illustrating a typical printed circuit board to which a build-up insulating film manufactured from an epoxy resin composition according to the present invention may be applied. As illustrated in FIG. 1, a printed circuit board 100 may be an embedded board including electronic parts therein. Specifically, the printed circuit board 100 may include an insulator 110 having a cavity, an electronic part 120 disposed in the cavity, and build-up layers 130 formed on one or more of upper and lower surfaces of the insulator 110 including the electronic part 120. The build-up layers 130 may include insulating layers 131 formed on one or more of the upper and lower surfaces of the insulator 110, and circuit layers 132 which are disposed on the insulating layers 131 and that may achieve interlayer connection.

An example of the electronic part 120 may include an active device such as a semiconductor device. Also, the printed circuit board 100 may further include one or more additional electronic parts, for example, a capacitor 140, a resistor 150, etc., in addition to the single electronic part 120. In embodiments of the present invention, the kind or number of the electronic parts is not limited. As such, the insulator 110 and the insulating layers 131 play a role in imparting insulating properties between the circuit layers or between the electronic parts, and also function as a support for maintaining rigidity of a package.

As such, in the case where the wiring density of the printed circuit board 100 is increased, to decrease noise between the circuit layers and also to reduce parasitic capacitance, the insulator 110 and the insulating layers 131 should have low permittivity. Furthermore, the insulator 110 and the insulating layers 131 should have low dielectric loss to increase insulation properties.

At least any one of the insulator 110 and the insulating layers 131 should have low permittivity and dielectric loss and should also have rigidity. In order to decrease the dielectric tangent, dielectric constant, permittivity, dielectric loss, and the coefficient of thermal expansion (CTE) of the insulating layers, the insulating film according to the present invention may be formed from an epoxy resin composition comprising an epoxy resin (A), an acid anhydride curing agent (B) having a value of molar polarizability/molar volume of 0.6 or less and having a fluorine group or a methyl group in the molecule thereof with a symmetric molecular structure, an inorganic filler (C), and a curing accelerator (D).

Epoxy Resin (A)

According to the present invention, the epoxy resin composition includes the epoxy resin in order to increase handleability of the dried resin composition. The epoxy resin is not particularly limited, but indicates a resin including one or more epoxy groups, preferably two or more epoxy groups, and more preferably four or more epoxy groups, in the molecule thereof.

Examples of the epoxy resin usable in the present invention may include bisphenol A type epoxy resin, bisphenol F type epoxy resin, bisphenol S type epoxy resin, phenol novolac epoxy resin, alkylphenol novolac epoxy resin, biphenyl type epoxy resin, aralkyl type epoxy resin, dicyclopentadiene type epoxy resin, naphthalenic epoxy resin, naphthol type epoxy resin, epoxy resin including a condensate of phenol and aromatic aldehyde having a phenolic hydroxyl group, biphenylaralkyl type epoxy resin, fluorene type epoxy resin, xanthene type epoxy resin, triglycidyl isocyanurate, rubber modified epoxy resin, and phosphorous epoxy resin, which may be used alone or in combination of two or more in the present invention.

In addition to the above epoxy resin, a thermosetting resin may be further included. Examples of the thermosetting resin may include unsaturated polyester resin, polyimide resin, bismaleimide resin, bismaleimide triazine resin, cyanate ester resin, vinyl resin, benzoxazine resin, benzocyclobutene resin, acryl, alkyd, phenol-formaldehyde resin, novolac, resol, melamine-formaldehyde resin, urea-formaldehyde resin, hydroxymethylfuran, isocyanate, diallyl phthalate, triallyl cyanurate, triallyl isocyanurate, unsaturated polyesterimide, and mixtures thereof. Particularly, at least one of a cyanate ester resin and a bismaleimide resin may be further included.

Cyanate Ester Resin

Useful in the present invention, the cyanate ester resin is not particularly limited, but examples thereof may include novolac type (phenol novolac, alkylphenol novolac, etc.) cyanate ester resin, dicyclopentadiene type cyanate ester resin, bisphenol type (bisphenol A, bisphenol F, bisphenol S, etc.) cyanate ester resin, and prepolymers in which a portion of the resin is formed into triazine, which may be used alone or in combination of two or more. The weight average molecular weight of the cyanate ester resin is not particularly limited, but may be 500˜4500, and preferably 600˜3000.

Specific examples of the cyanate ester resin may include a bifunctional cyanate resin, such as bisphenol A dicyanate, polyphenolcyanate(oligo(3-methylene-1,5-phenylenecyanate)), 4,4′-methylenebis(2,6-dimethylphenylcyanate), 4,4′-ethylidenediphenyldicyanate, hexafluoro bisphenol A dicyanate, 2,2-bis(4-cyanate)phenylpropane, 1,1-bis(4-cyanatephenylmethane), bis(4-cyanate-3,5-dimethylphenyl)methane, 1,3-bis(4-cyanatephenyl-1-(methylethylidene))benzene, bis(4-cyanatephenyl)thioether, bis(4-cyanatephenyl)ether, etc., a polyfunctional cyanate resin derived from phenol novolac, cresol novolac, phenol resin having a dicyclopentadiene structure, etc., and prepolymers in which a portion of the cyanate resin is formed into triazine, which may be used alone or in combinations of two or more.

Commercially available cyanate ester resin may include a phenol novolac type polyfunctional cyanate ester resin represented by the following Chemical Formula 1 (PT30, cyanate equivalent 124, available from Lonza Japan), a prepolymer represented by the following Chemical Formula 2 in which a portion or all of bisphenol A dicyanate is produced into triazine to form a trimer (BA230, cyanate equivalent 232, available from Lonza Japan), a dicyclopentadiene structure-containing cyanate ester resin represented by the following Chemical Formula 3 (DT-4000, DT-7000, available from Lonza Japan), etc.

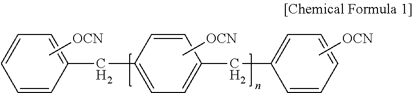

In Chemical Formula 1, n is an arbitrary integer (preferably 0˜20) on average.

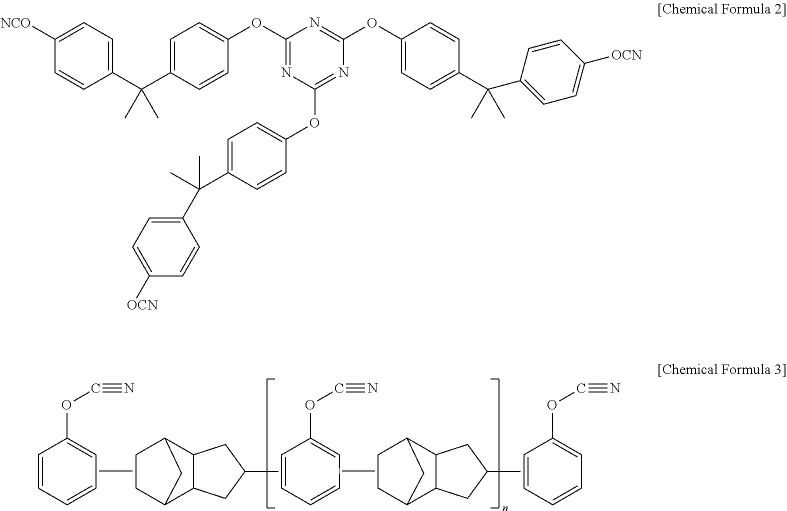

In Chemical Formula 3, n is an integer of 0˜5 on average.

The amount of the cyanate ester resin in the resin composition according to the present invention is not particularly limited, but the upper limit of the amount of the cyanate ester resin in the resin composition is 50 mass % or less, preferably 40 mass % or less, more preferably 30 mass % or less, and much more preferably 25 mass % or less, based on 100 mass % of nonvolatile content of the resin composition, in order to prevent peel strength with a conductive plating layer from decreasing. In contrast, the lower limit of the amount of the cyanate ester resin in the resin composition is 2 mass % or more, preferably 5 mass % or more, and more preferably 8 mass % or more, based on 100 mass % of nonvolatile content of the resin composition, in order to prevent a decrease in heat resistance, an increase in CTE, and an increase in dielectric tangent.

Bismaleimide Resin

An appropriate bismaleimide includes those represented by the following Chemical Formula 4.

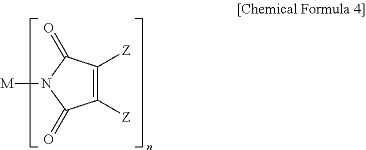

In Chemical Formula 4, M is a radical having a valence of n and 2˜40 carbons, and Z is independently hydrogen, a halogen, or an aromatic or aliphatic radical, and n is an integer of 0˜10.

In Chemical Formula 4, M may be aliphatic, alicyclic, aromatic, or heterocyclic. The useful bisimide is a bifunctional bismaleimide derived from aliphatic or aromatic diamine. Specific examples of the unsaturated imide may include 1,2-bismaleimidoethane, 1,6-bismaleimidohexane, 1,3-bismaleimidobenzene, 1,4-bismaleimidobenzene, 2,4-bismaleimidotoluene, 4,4′-bismaleimidodiphenylmethane, 4,4′-bismaleimidodiphenylether, 3,3′-bismaleimidodiphenylsulfone, 4,4′-bismaleimidodiphenylsulfone, 4,4′-bismaleimidodicyclohexylmethane, 3,5-bis(4-maleimidophenyl)pyridine, 2,6-bismaleimidopyridine, 1,3-bis(maleimidomethyl)cyclohexane, 1,3-bis(maleimidomethyl)benzene, 1,1-bis(4-maleimidophenyl)cyclohexane, 1,3-bis(dichloromaleimido)benzene, 4,4′-biscitraconimido diphenylmethane, 2,2-bis(4-maleimidophenyl)propane, 1-phenyl-1,1-bis(4-maleimidophenyl)ethane, α,α-bis(4-maleimidophenyl)toluene, 3,5-bismaleimido-1,2,4-triazole, N,N′-ethylene bismaleimide, N,N′-hexamethylene bismaleimide, N,N′-m-phenylene bismaleimide, N,N′-p-phenylene bismaleimide, N,N′-4,4′-diphenylmethane bismaleimide, N,N′-4,4′-diphenylether bismaleimide, N,N′-4,4′-diphenylsulfone bismaleimide, N,N′-4,4′-dicyclohexylmethane bismaleimide, N,N′-α,α′-4,4′-dimethylenecyclohexane bismaleimide, N,N′-m-xylene bismaleimide, N,N′-4,4′-diphenylcyclohexane bismaleimide and N,N-methylenebis(3-chloro-p-phenylene)bismaleimide, a variety of maleimides, and mixtures thereof.

Acid Anhydride Curing Agent (B)

According to the present invention, the acid anhydride curing agent is used to cure a complex with an epoxy resin resulting from a cross-linking reaction with the epoxy resin.

The acid anhydride curing agent used in the present invention is in a liquid phase or a solid phase, has a value of molar polarizability/molar volume of 0.6 or less, and has a fluorine group or a methyl group in the molecule thereof, with a symmetrical molecular structure.

As the value of molar polarizability/molar volume is lower, permittivity or dielectric loss may decrease, thus satisfying low permittivity or low dielectric loss required in the present invention. Thus, as the molar polarizability is lower or the molar volume is higher, permittivity or dielectric loss may decrease. The permittivity indicates the extent of charges accumulating in the molecule via localization of positive and negative charges in the molecule when a voltage is applied to a dielectric material. Briefly, the permittivity indicates the magnitude of polarization. Thus, in order to attain low permittivity, polarization should not occur or should be minimized.

In order to decrease the molar polarizability, the number of polar groups may be lowered in the molecule, a fluorine atom may be introduced, a methyl group may be introduced, or porosity may be provided. For example, in particular, because a fluorine atom has the greatest electrical negativity among all of the elements and the outermost electron thereof is very strongly attracted to the proton of the nucleus, polarization in the molecule may be reduced by virtue of the introduction of a fluorine atom.

Also to decrease the molar polarizability, the refractive index of a molecule may be lowered. A polymer having a low refractive index has low polarizability, and the dipole moment per unit volume induced by an electric field is low.

Also to decrease the molar polarizability, the molar volume may be increased. This molar volume may be increased using a bulky structure. As the molar volume increases, polarization is prevented via steric hindrance, etc., and thus polarity may decrease. Further, the acid anhydride curing agent is introduced, which is configured to have a symmetric molecular structure, and thus polarization is offset and decreased, thereby lowering polarity. For example, symmetry may be improved via meta bonding, and polarization may be reduced via the introduction of a triazine structure, a cyanate resin, a syndiotactic polystyrene, etc. Furthermore, a cyclic olefin, a branched structure, or bulky —CF₃, may be introduced. In particular, the structure in which the molar polarizability per molar volume is large is not introduced, and examples thereof may include —OH, —COOH, —CONH, etc.

The permittivity of the dielectric polymer may be determined by the equation of Clausius-Mossoti represented by Equation 1 below. As the value of molar polarizability/molar volume is lower, permittivity may decrease.

$$ɛ = \frac{1 + \frac{2 \sum {φ}_{i}}{\sum {V}_{i}}}{1 - \frac{2 \sum {φ}_{i}}{\sum {V}_{i}}} \qquad [ Equation 1 ]$$

In Equation 1, ∈ is the permittivity, φᵢ is the molar polarizability, and Vᵢ is the molar volume (cm³/mol).

Useful in the present invention, examples of the acid anhydride curing agent may include 2,2′-bis-(3,4-dicarboxyphenyl)hexafluoropropane dianhydride, pyromellitic dianhydride, 3,3′,4,4′-biphenyl tetracarboxylic acid dianhydride, 4,4′-oxydiphthalic acid anhydride, 3,3′,4,4′-diphenylsulfone tetracarboxylic acid dianhydride, 4,4′-bisphenol A dianhydride, hydroquinone diphthalic anhydride, ethylene glycol bis(trimellitic anhydride), ethylene tetracarboxylic dianhydride, naphthalene tetracarboxylic acid dianhydride, benzoquinone tetracarboxylic acid dianhydride, perylene tetracarboxylic acid dianhydride, biphenyl tetracarboxylic acid dianhydride, 1,6,7,12-tetrachloroperylene tetracarboxylic acid dianhydride, 1,2,3,4-cyclopentane tetracarboxylic acid dianhydride, 1,2,3,4-cyclobutane tetracarboxylic acid dianhydride, 1,2,4,5-cyclohexane tetracarboxylic acid dianhydride, 1,4,5,8-naphthalene tetracarboxylic acid dianhydride, 3,4,9,10-perylene tetracarboxylic acid dianhydride, 2,3,3′,4′-biphenyl-tetracarboxylic acid dianhydride, etc., which may be used alone or in combination of two or more. Particularly useful are 2,2′-bis-(3,4-dicarboxyphenyl)hexafluoropropane dianhydride, 1,2,3,4,-cyclopentane tetracarboxylic acid dianhydride, 1,2,3,4-cyclobutane tetracarboxylic acid dianhydride, and/or 1,2,4,5-cyclohexane tetracarboxylic acid dianhydride.

In the present invention, the acid anhydride curing agent is used in an amount of 80˜120 parts by weight, preferably 70˜110 parts by weight, and more preferably 60˜100 parts by weight, based on 100 parts by weight of the epoxy resin. If the amount of the acid anhydride curing agent is less than 80 parts by weight, the curing rate may decrease. In contrast, if the amount thereof exceeds 120 parts by weight, the unreacted curing agent may be left behind, thus increasing the moisture absorption of the insulating film, undesirably deteriorating electrical properties.

Inorganic Filler (C)

The resin composition according to the present invention includes an inorganic filler to decrease the coefficient of thermal expansion (CTE) of the epoxy resin. Although the amount of the inorganic filler (C) which decreases the CTE may vary depending on the required properties taking into consideration the end uses of the resin composition, it may be set to 60˜160 parts by weight based on 100 parts by weight of the epoxy resin. If the amount of the inorganic filler is less than 60 parts by weight, the CTE may increase. In contrast, if the amount thereof exceeds 160 parts by weight, adhesive strength may decrease.

Specific examples of the inorganic filler used in the present invention may include silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate, which may be used alone or in combinations of two or more. Particularly useful is silica.

Furthermore, in the case where the average particle size of the inorganic filler exceeds 5 μm, it is difficult to stably form a fine pattern when forming a circuit pattern on the conductive layer. Hence, the average particle size is set to 5 μm or less. In order to improve moisture resistance, the inorganic filler may be provided in the form of being surface-treated with a surface treatment agent, such as a silane coupling agent, etc. Particularly useful is silica having a diameter of 0.2˜2 μm.

Curing Accelerator (D)

The resin composition according to the present invention may contain a curing accelerator (D), and thereby may be efficiently cured. The curing accelerator used in the present invention may include a metallic curing accelerator, an imidazole-based curing accelerator, an amine-based curing accelerator, etc., which may be used alone or in combination of two or more in an amount typically used in the art.

Examples of the metallic curing accelerator include, but are not particularly to, organic metal complexes or organic metal salts of metals such as cobalt, copper, zinc, iron, nickel, manganese, tin, etc. Specific examples of the organic metal complex include an organic cobalt complex such as cobalt (II) acetylacetonate, cobalt (III) acetylacetonate, etc., an organic copper complex such as copper (II) acetylacetonate, etc., an organic zinc complex such as zinc (II) acetylacetonate or the like, an organic iron complex such as iron (III) acetylacetonate or the like, an organic nickel complex such as nickel (II) acetylacetonate or the like, and an organic manganese complex such as manganese (II) acetylacetonate, etc. Examples of the organic metal salt include zinc octylate, tin octylate, zinc naphthenate, cobalt naphthenate, tin stearate, zinc stearate, etc. From the point of view of curability and solubility in solvent, the metallic curing accelerator may be exemplified by cobalt (II) acetylacetonate, cobalt (II) acetylacetonate, zinc (II) acetylacetonate, zinc naphthenate, or iron (III) acetylacetonate. Particularly useful is cobalt (II) acetylacetonate or zinc naphthenate. These metallic curing accelerators may be used alone or in combination of two or more.

The imidazole-based curing accelerator is not particularly limited, but examples thereof may include imidazole compounds, including 2-methylimidazole, 2-undecylimidazole, 2-heptadecylimidazole, 1,2-dimethylimidazole, 2-ethyl-4-methylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidazolium trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1)]-ethyl-s-triazine, 2,4-diamino-6-[2′-methylimidazolyl-(1′)]ethyl-s-triazine isocyanurate adducts, 2-phenylimidazole isocyanurate adducts, 2-phenyl-4,5-dihydroxymethylimidazole, 2-phenyl-4-methyl-5-hydroxymethylimidazole, 2,3-dihydroxy-1H-pyro[1,2-a]benzimidazole, 1-dodecyl-2-methyl-3-benzylimidazolium chloride, 2-methylimidazoline, 2-phenylimidazoline, etc., and adducts of imidazole compounds and epoxy resins. These imidazole-based curing accelerators may be used alone or in combination of two or more.

The amine-based curing accelerator is not particularly limited, but examples thereof may include trialkylamines, including triethylamine, tributylamine, etc., and amine compounds, including 4-dimethylaminopyridine, benzyldimethylamine, 2,4,6-tris(dimethylaminomethyl)phenol, 1,8-diazabicyclo(5,4,0)-undecene (hereinafter referred to as “DBU”), etc. These amine-based curing accelerators may be used alone or in combination of two or more.

The amount of the curing accelerator is used in an amount of 0.1˜1.5 parts by weight, and preferably 0.2˜1 parts by weight, based on 100 parts by weight of the epoxy resin. If the amount of the curing accelerator is less than 0.1 parts by weight, desired curing acceleration effects cannot be obtained. In contrast, if the amount thereof exceeds 1.5 parts by weight, it is not easy to control the curing rate, and the physical and chemical properties of the cured product may deteriorate.

Thermoplastic Resin (E)

The epoxy resin composition according to the present invention may further include a thermoplastic resin to improve film formability of an epoxy resin composition or to improve mechanical properties of a cured product. Examples of the thermoplastic resin include phenoxy resin, polyimide resin, polyamideimide (PAI) resin, polyetherimide (PEI) resin, polysulfone (PS) resin, polyethersulfone (PES) resin, polyphenylene ether (PPE) resin, polycarbonate (PC) resin, polyetheretherketone (PEEK) resin, and/or polyester resin, etc., which may be used alone or in combination of two or more. The weight average molecular weight of the thermoplastic resin falls in the range of 5,000˜200,000. If the weight average molecular weight thereof is less than 5,000, improvements in film formability or mechanical strength become insignificant. In contrast, if the weight average molecular weight thereof exceeds 200,000, compatibility with the liquid crystal oligomer and the epoxy resin becomes poor, surface roughness may increase after a curing process, and the formation of a high-density fine pattern may become difficult. The weight average molecular weight was calculated based on the calibration curve of standard polystyrene at a column temperature of 40° C. using LC-9A/RID-6A as a measuring device available from Shimadzu Corporation, Shodex K-800P/K-804L/K-804L as a column available from Showa Denko, and chloroform (CHCl₃) as a mobile phase.

In the case where the thermoplastic resin is added to the resin composition according to the present invention, the amount of the thermoplastic resin in the resin composition is not particularly limited, but may be set to 0.1˜10 wt %, and preferably 1˜5 wt %, based on 100 wt % of nonvolatile content of the resin composition. If the amount of the thermoplastic resin is less than 0.1 wt %, there is no improvement in film formability or mechanical strength. In contrast, if the amount thereof exceeds 10 wt %, melting viscosity may increase and the surface roughness of the insulating layer after a wet roughening process may increase.

Other Additives (F)

The epoxy resin composition according to the present invention may further include a surface wetting agent, as necessary. The surface wetting agent is used to enhance the property of the epoxy composition which infiltrates a space between the chip and the substrate upon coating, and also to prevent the formation of a vacancy of the space. Examples thereof include, but are not limited to, BYK 018, BYK 019, BYK 021, BYK 024, BYK 066, BYK 909, etc., which may be used alone or in combination of two or more. The amount of the surface wetting agent is used in an amount of 0.1˜5 parts by weight, and preferably 0.1˜2 parts by weight, based on 100 parts by weight of the epoxy resin. If the amount of the surface wetting agent is less than 0.1 parts by weight, desired effects cannot be obtained. In contrast, if the amount thereof exceeds 5 parts by weight, flowability becomes excessive, undesirably deteriorating the properties.

The epoxy resin composition according to the present invention may further include an adhesion enhancer, as necessary. The adhesion enhancer is used to enhance the ability of the epoxy resin composition to adhere to the chip and the substrate, and may include, for example, silanes, isocyanates, sulfides, amines, etc. Examples thereof include octyltriethoxysilane, methyltriethoxysilane, methyltrimethoxysilane, tris-(3-(trimethoxysilyl)propyl)isocyanurate, tetraethyl ortho-silicate, ethyl polysilicate, vinyltriethoxysilane, vinyltrimethoxysilane, vinyl-tris-(2-methoxyethoxy)silane, vinylmethyldimethoxysilane, gamma-methacryloxypropyltriethoxysilane, gamma-methacryloxypropyltrimethoxysilane, beta-(3,4-epoxycyclohexyl)ethyltrimethoxysilane, gamma-glycidoxypropyltrimethoxysilane, gamma-2-mercaptopropyltrimethoxysilane, bis-(triethoxysilylpropyl)tetrasulfide, bis-(triethoxysilylpropyl)disulfide, 3-octanoylthio-1-propyltriethoxysilane, gamma-aminopropyltriethoxysilane, gamma-aminopropylsilsequioxane, gamma-aminopropyltrimethoxysilane, n-beta-(aminoethyl)-gamma-aminopropyltrimethoxysilane, triaminofunctional silane, bis-(gamma-trimethoxysilylpropyl)amine, delta-aminoneohexyltrimethoxysilane, n-(beta)-aminoethyl-gamma-aminopropylmethyldimethoxysilane, delta-aminoneohexylmethyldimethoxysilane, n-phenyl-gamma-aminopropyltrimethoxysilane, gamma-ureidopropyltrialkoxysilane, gamma-ureidopropyltrimethoxysilane, gamma-isocyanatopropyltriethoxysilane, gamma-isocyanatopropyltrimethoxysilane, etc., which may be used alone or in combination of two or more. The amount of the adhesion enhancer is used in an amount of 0.5˜3 parts by weight, and preferably 1˜2 parts by weight, based on 100 parts by weight of the epoxy resin. If the amount of the adhesion enhancer is less than 0.5 parts by weight, adhesion enhancement effects are insufficient. In contrast, if the amount thereof exceeds 3 parts by weight, this component participates in curing of the epoxy resin, thus deteriorating thermal, chemical, and mechanical properties. Particularly in the case of a silane-based adhesion enhancer, its amount is set so as to not exceed 2 parts by weight in order to prevent the thermal properties of the epoxy resin from deteriorating.

The insulating resin composition according to the present invention is prepared in the presence of an organic solvent. Taking into consideration solubility and miscibility of the resin and the other additives used in the present invention, examples of the organic solvent may include, but are not particularly limited to, 2-methoxy ethanol, acetone, methylethylketone, cyclohexanone, ethyl acetate, butyl acetate, cellosolve acetate, propylene glycol monomethyl ether acetate, ethylene glycol monobutyl ether acetate, cellosolve, butyl cellosolve, carbitol, butyl carbitol, xylene, dimethylformamide, and dimethylacetamide.

In addition, the epoxy resin composition according to the present invention may further include another resin, a leveling agent, a fire retardant, a diluent, a catalyst, a defoaming agent, an antifoaming agent, a deionizing agent, a dispersant, etc., in addition to the above components, within the scope of the present invention.

The insulating resin composition according to the present invention may be manufactured in the form of a dry film in a semi-solid phase using any process typically known in the art. For example, the resin composition may be formed into a film using a roll coater or a curtain coater and then dried, after which the resulting film is applied on a substrate and used as an insulating layer (or an insulating film) when manufacturing a multilayer printed circuit board using a building-up process.

An insulating film manufactured using the epoxy resin composition according to the present invention may be laminated on a copper clad laminate (CCL) serving as an inner layer upon manufacturing a printed circuit board. For example, an insulating film made of the epoxy resin composition may be laminated on an inner circuit board having a processed pattern, cured at 80˜110° C. for 20˜30 min, and subjected to desmearing, after which circuit layers may be formed using an electroplating process, resulting in a multilayer printed circuit board.

A better understanding of the present invention may be obtained via the following examples and comparative examples which are set forth to illustrate, but are not to be construed as limiting the present invention.

### Example 1

1,000 g of a naphthalene-modified epoxy resin having an average epoxy resin equivalent of 151, 250 g of a cresol novolac epoxy resin having an average epoxy resin equivalent of 206, 500 g of a phosphorous epoxy resin having an average epoxy resin equivalent of 590, and 1,787.04 g of a 66.7 wt % (solvent: 2-methoxy ethanol) 2,2′-bis-(3,4-dicarboxyphenyl)hexafluoropropane dianhydride curing agent were added together, and the resulting mixture was stirred in a solvent mixture of 316.54 g of MEK (Methyl Ethyl Ketone) and 464.64 g of 2-methoxy ethanol at room temperature at 300 rpm. Then, 65 wt % of silica having an average particle size of 0.3 μm was added thereto, and the resulting mixture was stirred at 400 rpm for 3 hr. Finally, 0.25 parts by weight of 2-ethyl-4-methylimidazole was added thereto, and the resulting mixture was stirred for 1 hr, thus preparing an insulating composition. The insulating composition thus prepared was applied onto a PET film using film casting, thus manufacturing a roll-shaped product.

### Comparative Example 1

1,000 g of a naphthalene-modified epoxy resin having an average epoxy resin equivalent of 151, 250 g of a cresol novolac epoxy resin having an average epoxy resin equivalent of 206, 500 g of a phosphorous epoxy resin having an average epoxy resin equivalent of 590, and 787.04 g of a 66.7 wt % (solvent: 2-methoxy ethanol) aminotriazine-based novolac curing agent were added together, and the resulting mixture was stirred in a solvent mixture of 316.54 g of MEK and 464.64 g of 2-methoxy ethanol at room temperature at 300 rpm. Then, 65 wt % of silica having an average particle size of 0.3 μm was added thereto, and the resulting mixture was stirred at 400 rpm for 3 hr. Finally, 0.25 parts by weight of 2-ethyl-4-methylimidazole was added thereto, and the resulting mixture was stirred for 1 hr, thus preparing an insulating composition. The insulating composition thus prepared was applied onto a PET film using film casting, thus manufacturing a roll-shaped product.

### Comparative Example 2

1,000 g of a naphthalene-modified epoxy resin having an average epoxy resin equivalent of 151, 250 g of a cresol novolac epoxy resin having an average epoxy resin equivalent of 206, 500 g of a phosphorous epoxy resin having an average epoxy resin equivalent of 590, and 800 g of a 66.7 wt % (solvent: 2-methoxy ethanol) bisphenol novolac curing agent were added together, and the resulting mixture was stirred in a solvent mixture of 316.54 g of MEK and 464.64 g of 2-methoxy ethanol at room temperature at 300 rpm. Then, 65 wt % of silica having an average particle size of 0.3 μm was added thereto, and the resulting mixture was stirred at 400 rpm for 3 hr. Finally, 0.25 parts by weight of 2-ethyl-4-methylimidazole was added thereto, and the resulting mixture was stirred for 1 hr, thus preparing an insulating composition. The insulating composition thus prepared was applied onto a PET film using film casting, thus manufacturing a roll-shaped product.

TABLE 1

| | Flammability | Moisture Absorption | | Loss |
|---|---|---|---|---|
| | rating | (%) | Permittivity | tangent |
| Ex. 1 | V0 | 1.08 | 3.2 | 0.010 |
| Comp. Ex. 1 | V0 | 1.01 | 3.5 | 0.016 |
| Comp. Ex. 2 | V0 | 1.05 | 3.5 | 0.015 |

When comparing the permittivity and the loss tangent in the case of using, as the acid anhydride-based curing agent, 2,2′-bis-(3,4-dicarboxyphenyl)hexafluoropropane dianhydride (Example 1), and the cases of using the aminotriazine-based novolac curing agent (Comparative Example 1) and the bisphenol novolac curing agent (Comparative Example 2), the permittivity was decreased by about 8.5% and the loss tangent was lowered by about 37% upon using the acid anhydride curing agent.

The dielectric constant and the loss tangent were determined by preparing samples using the compositions of Example 1 and Comparative Examples 1 and 2 according to Japanese Industrial Standard (JIS C 2565) and then measuring the permittivity and the loss tangent thereof at 5.8 GHz using a network analyzer.

As described hereinbefore, the present invention provides an epoxy resin composition for a build-up insulating film, an insulating film formed therefrom, and a multilayer printed circuit board having the insulating film. According to the present invention, in the case where an insulating film is manufactured using an epoxy resin composition comprising, as a curing agent, an acid anhydride-based curing agent having a value of molar polarizability/molar volume of 0.6 or less, permittivity can decrease, and the dielectric tangent can also decrease, thus exhibiting improved dielectric properties. Therefore, the epoxy resin composition according to the present invention can be appropriately applied to insulating films or products such as printed circuit boards.

Although the embodiments of the present invention have been disclosed for illustrative purposes, those skilled in the art will appreciate that a variety of different modifications, additions, and substitutions are possible, without departing from the scope and spirit of the invention as disclosed in the accompanying claims.

Accordingly, such modifications, additions, and substitutions should also be understood as falling within the scope of the present invention.

What is claimed is:

1. An epoxy resin composition for a build-up insulating film, comprising:
an epoxy resin (A);
an acid anhydride curing agent (B) having a value of molar polarizability/molar volume of 0.6 or less and having a fluorine group or a methyl group in a molecule thereof with a symmetric molecular structure;
an inorganic filler (C); and
a curing accelerator (D).

2. The epoxy resin composition of claim 1, comprising 100 parts by weight of the epoxy resin, 80˜120 parts by weight of the acid anhydride curing agent, 60˜160 parts by weight of the inorganic filler, and 0.1˜1.5 parts by weight of the curing accelerator.

3. The epoxy resin composition of claim 1, wherein the acid anhydride curing agent having the value of molar polarizability/molar volume of 0.6 or less and having the fluorine group or the methyl group in the molecule thereof with the symmetric molecular structure is at least one selected from the group consisting of 2,2′-bis-(3,4-dicarboxyphenyl)hexafluoropropane dianhydride, 1,2,3,4-cyclopentane tetracarboxylic acid dianhydride, 1,2,3,4-cyclobutane tetracarboxylic acid dianhydride, and 1,2,4,5-cyclohexane tetracarboxylic acid dianhydride.

4. The epoxy resin composition of claim 1, wherein the inorganic filler (C) is at least one selected from the group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

5. The epoxy resin composition of claim 1, wherein the curing accelerator (D) is at least one selected from the group consisting of 2-methylimidazole, 2-undecylimidazole, 2-heptanedecylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-cyanoethyl-2-undecyl-imidazolium trimellitate, 1-cyanoethyl-2-phenyl-imidazolium trimellitate, 2,4-diamino-6-(2′-methylimidazol-(1′))-ethyl-s-triazine, 2,4-diamino-6-(2′-ethyl-4-methylimidazol-(1′))-ethyl-s-triazine, 2,4-diamino-6-(2′-undecylimidazol-(1′))-ethyl-s-triazine, 2-phenyl-4,5-dihydroxy-methylimidazole, 2-phenyl-4-methyl-5-hydroxymethylimidazole, 2-phenyl-4-benzyl-5-hydroxymethylimidazole, 4,4′-methylene-bis-(2-ethyl-5-methylimidazole), 2-aminoethyl-2-methylimidazole, 1-cyanoethyl-2-phenyl-4,5-di(cyanoethoxymethyl)imidazole, 1-dodecyl-2-methyl-3-benzylimidazolium chloride, and imidazole-containing polyamide.

6. The epoxy resin composition of claim 1, further comprising at least one thermoplastic resin selected from the group consisting of a phenoxy resin, a polyimide resin, a polyamideimide (PAI) resin, a polyetherimide (PEI) resin, a polysulfone (PS) resin, a polyethersulfone (PES) resin, a polyphenylene ether (PPE) resin, a polycarbonate (PC) resin, a polyetheretherketone (PEEK) resin, and a polyester resin.

7. The epoxy resin composition of claim 1, further comprising at least one of a cyanate ester resin and a bismaleimide resin.

8. An insulating film manufactured using the epoxy resin composition of claim 1.

9. A multilayer printed circuit board comprising the insulating film of claim 8.
